(19) United States
(12) Patent Application Publication
(10) Pub. No.: US 2024/0260239 A1
(43) Pub. Date: Aug. 1, 2024

(54) Electronic Assembly

(71) Applicant: Vitesco Technologies Germany GmbH, Regensburg (DE)

(72) Inventor: Göran Schubert, Laubenhaidstraße 19 (DE)

(73) Assignee: Vitesco Technologies Germany GmbH, Regensberg (DE)

(21) Appl. No.: 18/633,578

(22) Filed: Apr. 12, 2024

Related U.S. Application Data
(63) Continuation of application No. PCT/EP2022/077958, filed on Jul. 10, 2022.

(30) Foreign Application Priority Data
Oct. 13, 2021 (DE) 10 2021 211 519.5

(51) Int. Cl. H05K 7/20; H02M 7/00; H05K 1/02

(52) U.S. Cl. CPC H05K 7/2089; H02M 7/003; H05K 1/0298

(57) ABSTRACT

An electronic assembly having an electrical DC link with a positive pole and a negative pole is provided. The electronic assembly includes at least one half bridge having an electronic high-side switch connected to the positive pole and an electronic low-side switch connected to the negative pole. The assembly further includes at least one metal low-side cooling block on which at least one low-side switch is arranged, and for each high-side switch a metal high-side cooling block on which the high-side switch is arranged. The cooling blocks have cooling channels connected to one another. The two electronic switches are electrically connected by a connecting line, which has a half-bridge tap of the half bridge, and by a compensation line, which runs parallel to the connecting line, to the high-side switch and to the low-side switch.

### CROSS-REFERENCE TO RELATED APPLICATIONS

This application claims the benefit of PCT Application PCT/EP2022/077958, filed Oct. 7, 2022, which claims priority to German Application 10 2021 211 519.5, filed Oct. 13, 2021. The disclosures of the above applications are incorporated herein by reference.

### TECHNICAL FIELD

The disclosure relates to an electronic assembly having at least one half bridge which has two electronic switches connected in series.

### BACKGROUND

Such an electronic assembly is used, for example, in voltage regulators and voltage transformers. The electronic switches of the assembly are usually applied to one side of an electrically insulating component carrier, for example a ceramic, for example by soldering or sintering. The component carrier is ordinarily coated with metal on both sides, for example with copper, for the purpose of heat distribution. The lower metal-coated side of the component carrier is often applied, for example by soldering or sintering, to a shielding metal housing of a control device which is passed through by cooling channels. When a coolant flows through these cooling channels, the heat energy absorbed by the coolant can be transported to the outside, that is to say away from the electronic switches.

In this case, the component carrier forms the bottleneck of the heat transfer path. Due to the transfer of the heat by way of lattice vibrations of the insulator, only a considerably lower heat flow can be transported than by metals whose heat transfer is based on moving electrons, for example only one tenth to one third of the heat flow which is able to be transported by a metal.

Moreover, the component carrier which is coated with metal on both sides forms a plate capacitor whose capacitance can be in a high pF range. The current driven through this capacitance by the switching voltages of the electronic switches is still in the mA range for inverters or converters in the multiple kW range at a frequency of 10 MHz. Currents in this frequency range are not allowed to exceed 1.3 μA; however, in order to comply with the emission limit values.

Bond wires are ordinarily also used to electrically connect the electronic switches. This creates large-area circuits which in the case of currents of several hundred amperes result in strong magnetic fields which penetrate and possibly disturb the environment. The electric fields which occur in the case of potential differences for example in the kV range in the system also project far into and can possibly disturb the surrounding area in the case of this construction technology.

### SUMMARY

The disclosure provides an electronic assembly having at least one half bridge which has two electronic switches connected in series, where the electronic assembly is improved in terms of cooling and electromagnetic compatibility.

The electronic assembly includes: an electrical DC link having a positive pole and a negative pole; at least one half bridge having an electronic high-side switch connected to the positive pole and an electronic low-side switch connected to the negative pole; for each high-side switch a metal high-side cooling block on which the high-side switch is arranged; at least one metal low-side cooling block on which at least one low-side switch is arranged; and a closed metal housing in which the DC link, each half bridge and each cooling block are arranged and which has coolant connections for supplying and discharging a coolant. The cooling blocks each have at least one cooling channel and the cooling channels are connected to one another and to the coolant connections such that a coolant is able to be conducted between the coolant connections through the cooling channels. The high-side switch and the low-side switch of each half bridge are electrically connected by a connecting line, which has a half-bridge tap of the half bridge, and by a compensation line, which runs parallel to the connecting line, to the high-side switch and to the low-side switch and in which a half-bridge capacitor is arranged. The high-side cooling blocks are electrically insulated from one another, from the positive pole and from each low-side cooling block. Additionally, each low-side cooling block is insulated from the connecting lines and is electrically conductively connected to the negative pole and to the housing.

The terms high-side switch and low-side switch are used here to distinguish between the electronic switches connected to the positive pole (high-side switches) and the electronic switches connected to the negative pole (low-side switches). The terms thus relate to the electrical interconnection of the switches in the assembly, not to the physical design of the switches. Physically, the high-side switches and the low-side switches can have an identical design. The terms high-side cooling block and low-side cooling block are used here to distinguish between a cooling block on which a high-side switch is arranged and a cooling block on which at least one low-side switch is arranged. These terms therefore relate to the assignment of the respective cooling block to a high-side switch or to at least one low-side switch, not to the physical design of the cooling block. A high-side cooling block can therefore be designed physically similar to a low-side cooling block.

In some implementations, the electronic assembly according to the disclosure differs from the above-described conventional assemblies by virtue of improved cooling, on the one hand, and by virtue of improved electromagnetic compatibility, on the other hand.

The cooling is improved by the fact that the assembly has no electrically insulating component carrier to which the high-side switches and low-side switches are applied. Instead, these switches are each arranged directly on a metal cooling block which has at least one cooling channel through which a coolant is able to be conducted. This substantially improves the heat dissipation from the switches in comparison with an assembly having an electrically insulating component carrier on which the switches are arranged.

The electromagnetic compatibility is improved in comparison with conventional assemblies by way of compensation of magnetic fields which are generated by the electrical currents flowing through the switches, on the one hand, and by virtue of spatial limitation of electric fields which are induced by potential differences between electrical potentials of the assembly, on the other hand.

The compensation of the magnetic fields is achieved by the fact that a compensation line in which a half-bridge capacitor is arranged runs parallel to the high-side switch, to the low-side switch and the connecting line thereof of each half bridge. The compensation line provides a return-flow path for the high-frequency current component which flows via the connecting line, the high-side switch and the low-side switch. The high-frequency current flowing in the compensation line is opposite to the high-frequency current component flowing in the connecting line, the high-side switch and the low-side switch and therefore generates a magnetic field which at least partially compensates for the magnetic field generated by the high-frequency current component flowing in the connecting line, the high-side switch and the low-side switch.

The spatial limitation of the electric fields is achieved by the fact that the housing of the assembly is closed and connected to the negative pole of the DC link. This limits the electric fields essentially to the interior of the housing and electrical currents generated by these fields are supplied back to their sources on short paths.

In some implementations, the electronic assembly has exactly one low-side cooling block on which all the low-side switches are arranged. This configuration of the disclosure, if the assembly has a plurality of half bridges having electronic switches, advantageously reduces the number of components of the assembly in comparison with an embodiment having a plurality of low-side cooling blocks, for example having a low-side cooling block for each low-side switch.

In some examples, the DC link has a capacitor unit with a capacitance which functionally is greater by a factor in the range from 10 to 50 than the capacitance of each half-bridge capacitor which is intended to carry the high-frequency current components in the MHz to GHz range.

In some implementations, the connecting line and the compensation line of each half bridge run at a distance of at most 3 mm from one another. This example takes into account that the above-described compensation of the magnetic fields which are generated by the currents flowing in the connecting line, the high-side switch and the low-side switch and the compensation line of a half bridge increases as the distance between the compensation line and the connecting line, the high-side switch and the low-side switch decreases. As small a distance as possible between the compensation line and the connecting line is therefore advantageous.

In some examples, each high-side cooling block is arranged at a distance of at most 10 mm from each low-side cooling block. This example takes into account that a high-side cooling block is in practice always at a different electrical potential to a low-side cooling block. This potential difference induces an electric field, the spatial extent of which can be reduced by reducing the distance between the high-side cooling block and the low-side cooling block. A small distance between the high-side cooling block and the low-side cooling block is therefore advantageous in order to limit the spatial extent of the electric field.

In some implementations, the connecting line, the high-side switch and the low-side switch and the compensation line of each half bridge have the same width or the same width and thickness. This advantageously allows particularly good compensation of the magnetic fields by virtue of the connecting line, the high-side switch and the low-side switch and the compensation line having an identical design.

In some examples, the electronic assembly has a multi-layer printed circuit board which has a first layer having contact elements for the connecting lines, the high-side switches and the low-side switches of the half bridges, and a second layer in which compensation line sections of the compensation lines run. Such a printed circuit board advantageously allows the contact elements of the connecting lines, the high-side switch and the low-side switch and compensation line sections to be arranged at a defined, very small distance from one another in mutually different layers of the printed circuit board. Furthermore, no bond wires, which have the above-mentioned disadvantages, are used for electrically connecting the high-side switch and the low-side switch of a half bridge.

The printed circuit board may further have a third layer having an electrically conductive first voltage supply surface connected to the positive pole, and a fourth layer having an electrically conductive second voltage supply surface connected to the negative pole. The two voltage supply surfaces advantageously form an extensive voltage supply which allows the return flow of high-frequency electrical currents to the sources (namely the electronic switches) on short paths. Arranging the voltage supply surfaces in layers of the printed circuit board further allows the poles of this voltage supply to be arranged at a defined, very small distance from one another, as a result of which the electric field generated by the voltage supply surfaces is advantageously spatially limited. Since the negative pole ordinarily predefines the reference potential of the electronic assembly at the same time, the printed circuit board can advantageously also have further layers, for example on a side of the fourth layer facing away from the third layer, for example for wiring and fitting control and evaluation circuits of the assembly which are related to the reference potential.

Moreover, the printed circuit board can have a fifth layer on or in which all the half-bridge capacitors are arranged. Arranging the half-bridge capacitors on or in a fifth, outer layer of the printed circuit board is useful since the half-bridge capacitors have a larger overall height than the remaining compensation line sections and arranging the half-bridge capacitors in the same layer as these compensation line sections can therefore be inconvenient.

In a further configuration of the disclosure, the housing of the electronic assembly is at least partially filled with a dielectric, for example with a dielectric which has a relative permittivity of at least 3. The dielectric allows a dielectric strength of the interior of the housing to be increased, as a result of which the distances between components with high potential differences in the interior of the housing can be reduced, as a result of which the electric fields generated by the potential differences are in turn advantageously spatially limited.

The dielectric is furthermore, for example, a thermoplastic, a thermoset or an insulating potting compound. As a result, simple mechanical fixing of components such as the cooling blocks in the interior of the housing can in particular be achieved by the dielectric.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a perspective illustration of components of an exemplary electronic assembly,

FIG. 2 shows a perspective illustration of components of the assembly which are arranged in a housing of an electronic assembly,

FIG. 3 shows a perspective illustration of components of the assembly which are arranged in a housing of an electronic assembly as in FIG. 2 having a printed circuit board arranged in the housing,

FIG. 4 shows a perspective illustration of components of the assembly which are arranged in a housing of an electronic assembly as in FIG. 2 having components arranged on a first layer of a printed circuit board,

FIG. 5 shows a perspective illustration of components of the assembly which are arranged in a housing of an electronic assembly as in FIG. 2 having a second layer of a printed circuit board,

FIG. 6 shows the same illustration as in FIG. 5 having half-bridge capacitors arranged on top of the second layer of the printed circuit board,

FIG. 7 shows a perspective illustration of components of the assembly which are arranged in a housing of an electronic assembly as in FIG. 2 having a third layer of a printed circuit board,

FIG. 8 shows a perspective illustration of components of the assembly which are arranged in a housing of an electronic assembly as in FIG. 2 having a fourth layer of a printed circuit board,

FIG. 9 shows a perspective illustration of the components, illustrated in FIG. 1, of an electronic assembly having a dielectric,

FIG. 10 shows a perspective illustration of an electronic assembly having a closed housing,

FIG. 11 schematically shows a first exemplary embodiment of a cooling system of an electronic assembly,

FIG. 12 schematically shows a second exemplary embodiment of a cooling system of an electronic assembly,

FIG. 13 schematically shows a third exemplary embodiment of a cooling system of an electronic assembly.

Like reference symbols in the various drawings indicate like elements.

### DETAILED DESCRIPTION

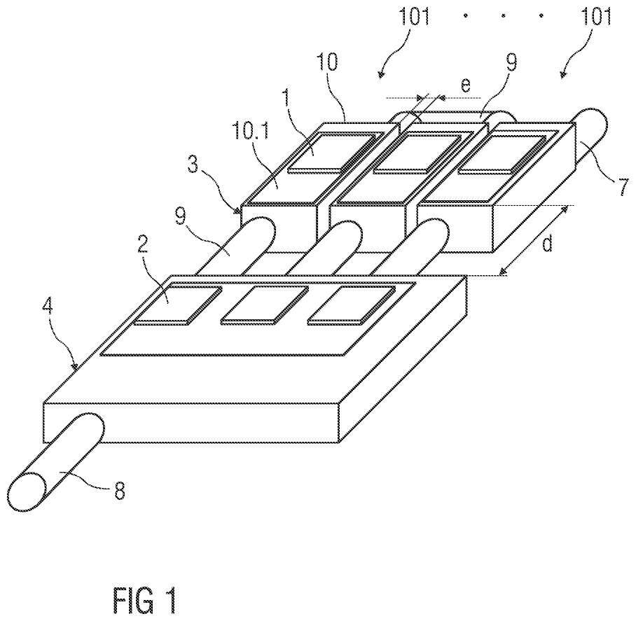

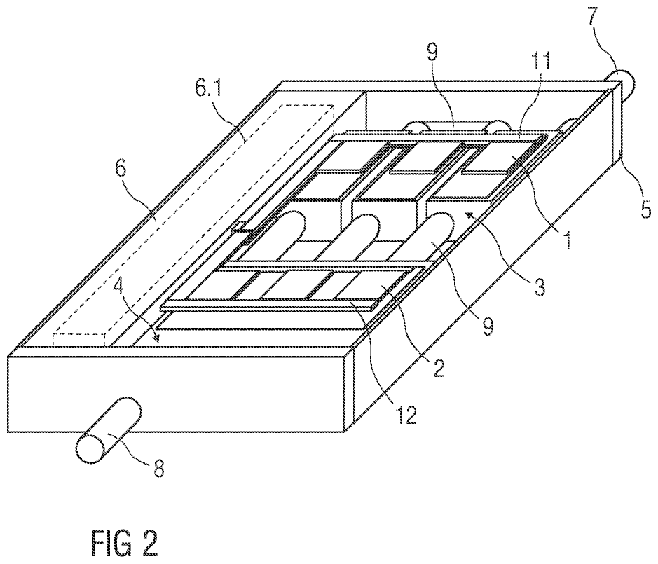

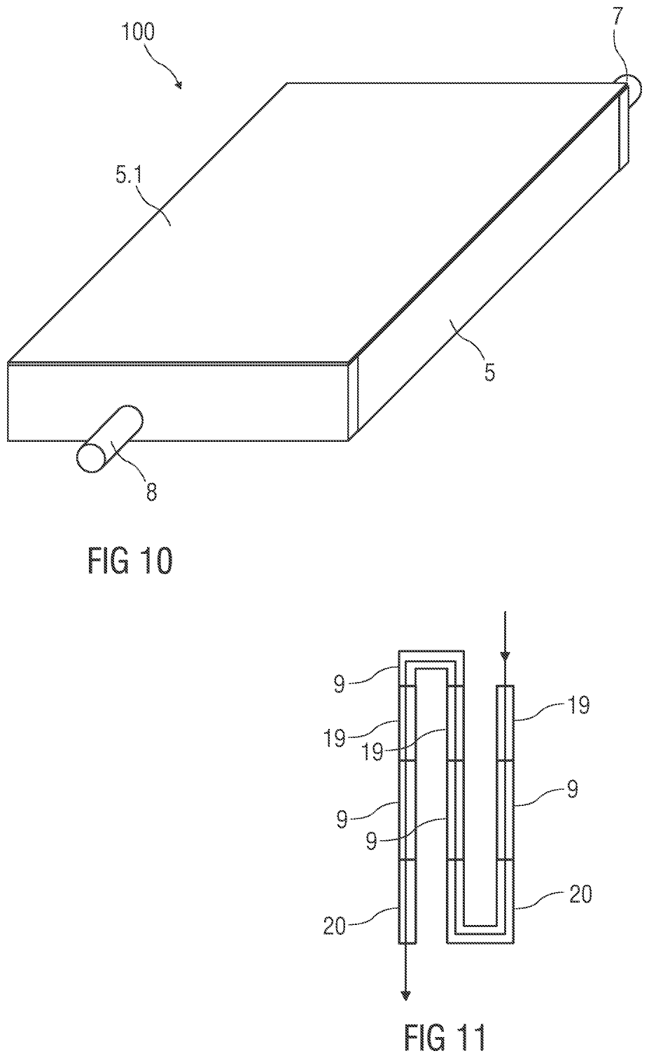

FIGS. 1 to 10 show perspective illustrations of an exemplary electronic assembly 100 according to the disclosure (illustrated in FIG. 10) or of parts of the assembly 100 (illustrated in FIGS. 1 to 9). The assembly 100 includes an electrical DC link 6.1 (schematically illustrated in FIG. 2) having a positive pole and a negative pole and a capacitor unit. The electrical potential of the negative pole defines a reference potential (ground potential) of the assembly 100. The DC link 6.1 is arranged in a DC link housing 6. The assembly 100 further includes three half bridges 101. Each half bridge 101 having an electronic high-side switch 1 connected to the positive pole and an electronic low-side switch 2 connected to the negative pole, where switches are electrically connected in series. Moreover, the assembly 100 includes three metal high-side cooling blocks 3 on each of which one of the high-side switches 1 is arranged, and one low-side cooling block 4 on which the low-side switches 2 are arranged. The DC link housing 6, the half bridges 101 and the cooling blocks 3, 4 are arranged in a metal housing 5 of the assembly 100. The housing 5 is closed by a housing cover 5.1 and has two coolant connections 7, 8 for supplying and discharging a coolant.

It is assumed below that the high-side switches 1 and the low-side switches 2 are each in the form of a transistor having a semiconductor with a wide bandgap (Wide Bandgap Transistor, abbreviated WBT), e.g., realized in GaN or SiC technology. In other examples, however, they can each also be in the form of another electronic switch, for example in the form of an IGBT (abbreviation for insulated-gate bipolar transistor) and a freewheeling diode connected in anti-parallel. In the latter case, the terms drain, source and gate used for the electrical connections of a WBT can optionally be replaced by corresponding terms, for example in the case of an IGBT drain can be replaced by collector and source by emitter.

FIG. 1 (FIG. 1) shows the cooling blocks 3, 4, the high-side switches 1 and the low-side switches 2. The cooling blocks 3, 4 have cooling channels 19, 20 (see FIG. 11) connected to one another and to the coolant connections 7, 8 and through which the coolant is able to be conducted between the coolant connections 7, 8. The cooling channels 19, 20 of the cooling blocks 3, 4 are connected to one another by coolant lines 9 which are each, for example, in the form of a pipe or a tube.

The high-side cooling blocks 3 are arranged next to one another at a distance e from one another. Each high-side cooling block 3 is arranged at a distance d from the low-side cooling block 4. The distance e is, for example, at most 30 mm; the distance d is, for example, at most 10 mm.

As shown, each cooling block 3, 4 has a main body 10 and a connecting metal layer 10.1 applied thereon, on which connecting metal layer the respective high-side switch 1 is applied or the low-side switches 2 are applied. In some examples, the connecting metal layers 10.1 can be omitted if the main bodies 10 of the cooling blocks 3, 4 are each made of a suitable metal such that the high-side switches 1 can each be applied directly on the main body 10 of a high-side cooling block 3 and the low-side switches 2 can each be applied directly to the main body 10 of the low-side cooling block 4.

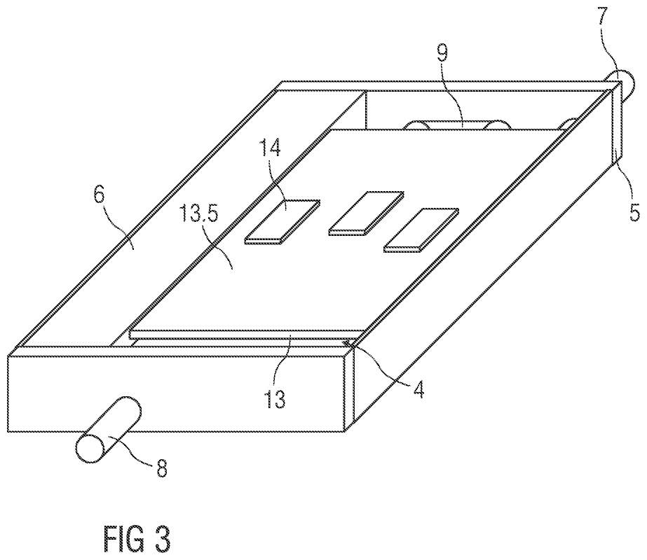

FIG. 2 shows the cooling blocks 3, 4, the high-side switches 1, the low-side switches 2 and the DC link housing 6 in the housing 5 which is illustrated without the housing cover 5.1 here and in FIGS. 3 to 8. The DC link housing 6 is arranged laterally next to the cooling blocks 3, 4. A positive high-potential busbar 11 and a negative high-potential busbar 12 are led out from the DC link housing 6. The positive high-potential busbar 11 connects the high-side switches 1 to the positive pole. The negative high-potential busbar 12 connects the low-side switches 2 to the negative pole. The high-side cooling blocks 3 are electrically insulated from one another, from the positive high-potential busbar 11 and from the low-side cooling block 4. The low-side cooling block 4 is insulated from connecting lines 15, which each electrically connect the high-side switch 1 and the low-side switch 2 of a half bridge 101 to one another, and is electrically conductively connected to the negative pole and to the housing 5.

FIGS. 3 to 8 show the interconnection of the high-side switches 1 and of the low-side switches 2 by a multi-layer printed circuit board 13.

FIG. 3 shows the arrangement of the printed circuit board 13 on top of the high-side switches 1 and the low-side switches 2. For each half bridge 101, a half-bridge capacitor 14 is arranged on a fifth layer 13.5 of the printed circuit board 13, which fifth layer faces away from the high-side switches 1 and the low-side switches 2. Each half-bridge capacitor 14 has, for example, a capacitance which is less than the capacitance of the capacitor unit of the DC link 6.1 by a factor in the range from 10 to 50. Furthermore, each half-bridge capacitor 14 may be a surface-mounted device (SMD) having a small overall height, for example as a film capacitor, silicon capacitor or ceramic capacitor.

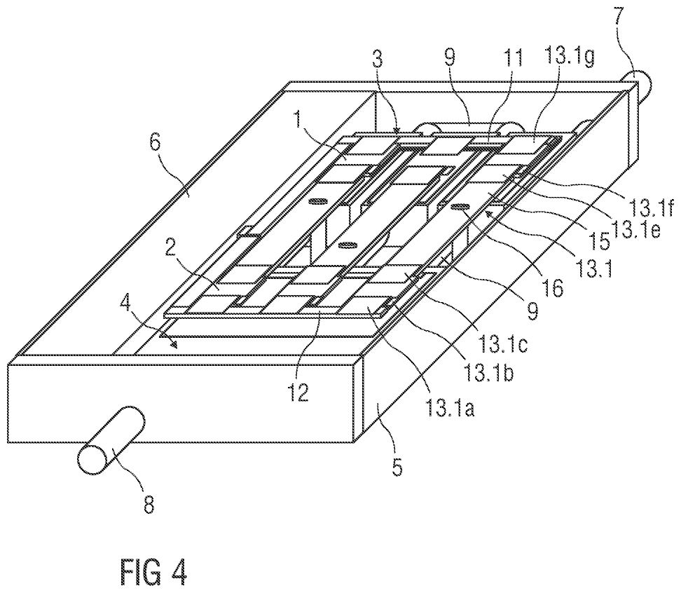

FIG. 4 shows contact elements 13.1a to 13.1c and 13.1e to 13.1g which are arranged on a first layer 13.1 of the printed circuit board 13, which first layer faces toward the high-side switches 1, the low-side switches 2 and the connecting lines 15, and which realize the interconnection of the high-side switches 1 and low-side switches 2 the connecting lines 15 to form half bridges 101. Each connecting line 15 runs between the high-side switch 1 and the low-side switch 2 of a half bridge 101 and has a half-bridge tap 16 of the half bridge 101.

The half-bridge taps 16 are arranged offset with respect to one another. As a result, connecting a field-compensated three-phase cable to the half-bridge taps 16 can be made easier, for example. A magnetic field surrounding the half-bridge taps 16 can, for example, be used for the inductive phase current measurement of a three-phase load connected to the half-bridge taps 16.

Each contact element 13.1a connects the negative high-potential busbar 12 and thus the negative pole to the source of a low-side switch. Each contact element 13.1c connects a connecting line 15 to the drain of a low-side switch 1. Each contact element 13.1e connects a connecting line 15 to the source of a high-side switch 1 and thus to the associated high-side cooling block 3. Each contact element 13.1g connects the positive high-potential busbar 11 and thus the positive pole to the drain of a high-side switch 1. Each contact element 13.1b makes contact with the gate of a low-side switch 2. Each contact element 13. If makes contact with the gate of a high-side switch 1.

The connecting lines 15, the positive high-potential busbar 11 and the negative high-potential busbar 12 are each flush with their associated high-side switches 1 and/or low-side switches 2, as a result of which easy electrical contacting and connection to these switches is made possible. The connecting lines 15 are therefore flat and wide, which also has an advantageous effect on the heat transfer at the connecting points to the switches 1, 2 and on the reduction of the inductance of the half-bridge arrangement.

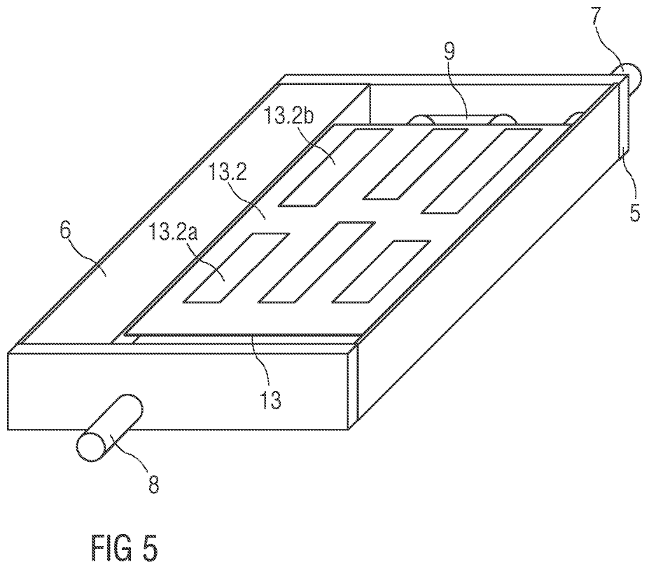

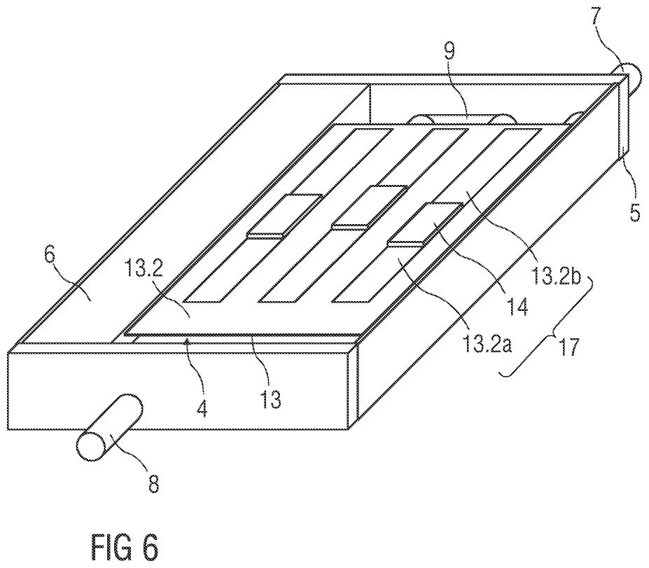

FIG. 5 and FIG. 6 show a second layer 13.2 of the printed circuit board 13. The second layer is arranged on top of the first layer 13.1. FIG. 6 additionally shows the arrangement of the half-bridge capacitors 14 on top of the second layer 13.2.

The second layer 13.2 has for each half bridge 101 two compensation line sections 13.2a and 13.2b which are each electrically connected, for example via a through hole in the printed circuit board 13, at one end to the negative pole or to the positive pole and at the other end to the half-bridge capacitor 14 of the half bridge 101 and together with this half-bridge capacitor 14 form a compensation line 17 which runs parallel to the connecting line 15, to the high-side switch 1 and to the low-side switch 2 of the half bridge 101. The compensation line sections 13.2a and 13.2b may have the same width or the same width and thickness as the connecting lines 15 and the high-side switches 1 and low-side switches 2. Each compensation line 17 provides a return-flow path for a current which flows via the corresponding connecting line 15 and the corresponding high-side switch 1 and low-side switch 2. The current flowing in the compensation line 17 is opposite to the current flowing in the connecting line 15, the high-side switch 1 and the low-side switch 2 and therefore generates a magnetic field which at least partially compensates for the magnetic field generated by the current flowing in the connecting line 15, the high-side switch 1 and the low-side switch 2. Moreover, high-frequency components of electric fields corresponding to these currents are spatially limited to an area around the compensation lines 17 and connecting lines 15, the high-side switches 1 and low-side switches 2.

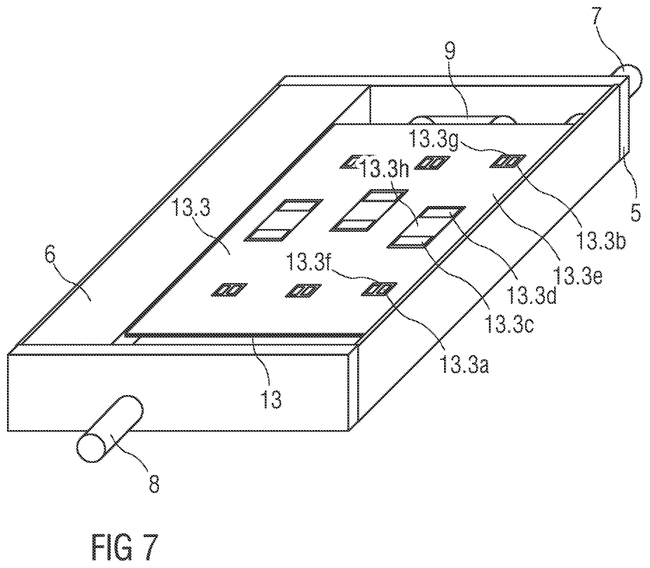

FIG. 7 shows a third layer 13.3 of the printed circuit board 13, which third layer is arranged on top of the second layer 13.2. The third layer 13.3 has an electrically conductive first voltage supply surface 13.3e which is electrically connected to the positive high-potential busbar 11 and thus to the positive pole. For example, the high-potential busbar 11 is for instance electrically connected to the first voltage supply surface 13.3e every 2 cm.

The first voltage supply surface 13.3e has for each half bridge 101 three recesses 13.3f, 13.3g, 13.3h. A pair of control connections 13.3a for the low-side switch 2 of the half bridge 101, for example for the gate and source thereof, are led through the first recess 13.3f. A pair of control connections 13.3b for the high-side switch 1 of the half bridge 101, for example for the gate and source thereof, are led through the second recess 13.3g. A contact 13.3c connected to the negative pole and a contact 13.3d connected to the positive pole are led through the third recess 13.3h, each of which contacts are connected to an electrode of the half-bridge capacitor 14 of the half bridge 101.

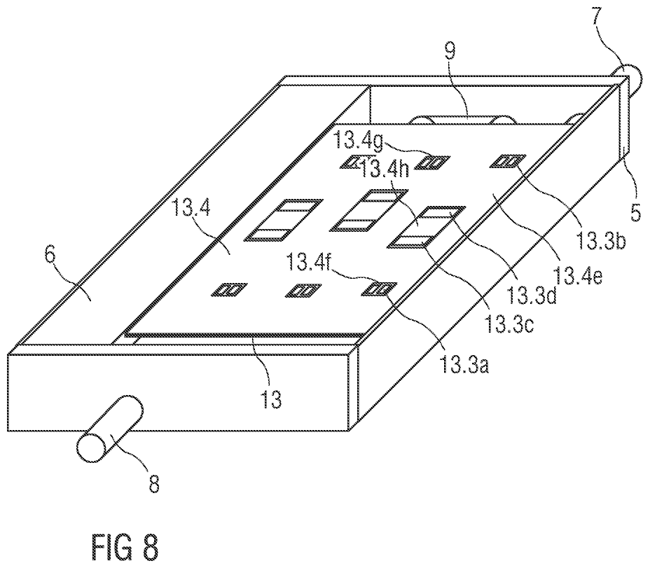

FIG. 8 shows a fourth layer 13.4 of the printed circuit board 13, which fourth layer is arranged on top of the third layer 13.3. The fourth layer 13.4 has an electrically conductive second voltage supply surface 13.4e (grounding surface) which is electrically connected to the negative high-potential busbar 12 and thus to the negative pole. For example, the negative high-potential busbar 12 is for instance electrically connected to the second voltage supply surface 13.4e every 2 cm.

The second voltage supply surface 13.4e has for each half bridge 101 three recesses 13.4f, 13.4g, 13.4h which correspond to the recesses 13.3f, 13.3g, 13.3h of the first voltage supply surface 13.3e.

The numbering of the layers 13.1 to 13.5 does not necessarily imply a physical arrangement of the layers 13.1 to 13.5 corresponding to this numbering. The printed circuit board 13 can also have further layers which are not mentioned here, for example a sixth layer arranged between the fourth layer 13.4 and the fifth layer 13.5.

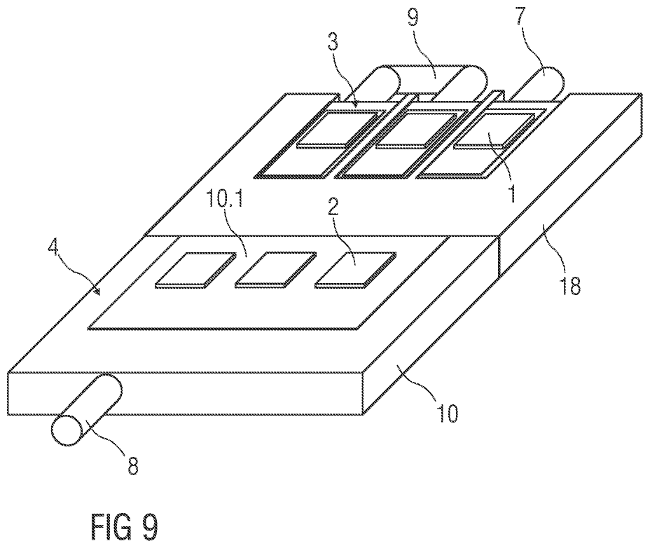

FIG. 9 shows a dielectric 18 with which the housing 5 (not illustrated in FIG. 9) is optionally partially filled. The dielectric 18 fills in the gaps between the cooling blocks 3, 4 and between the high-side cooling blocks 3 and the DC link housing 6 and the wall of the housing 5 opposite thereto and the printed circuit board 13. For example, the dielectric 18 has a relative permittivity of at least 3. The dielectric 18 allows a dielectric strength of the interior of the housing 5 to be increased, as a result of which the distances between components with high potential differences in the interior of the housing 5 can be reduced, as a result of which the electric fields generated by the potential differences are in turn spatially limited. Moreover, the increased permittivity of the dielectric of at least 3, compared with air of 1, leads to the electric field being concentrated in the dielectric 18 and thus to the field being reduced outside. Furthermore, the dielectric 18 can, for example, be a thermoplastic or a thermoset or a potting compound. As a result, simple mechanical fixing of components such as the cooling blocks 3, 4 in the interior of the housing 5 can be achieved.

FIG. 10 shows the housing 5 of the assembly 100 closed by the housing cover 5.1. The closed housing 5 and the connection of the housing 5 to the negative pole spatially limits an electric field, which surrounds the high-side switches 1, the low-side switches 2 and the DC link 6.1 and which is generated by the potential differences, essentially to the interior of the housing 5 and electrical currents induced by the electric field are supplied back to their sources on short paths.

FIGS. 11 to 13 schematically show different exemplary embodiments of the cooling system of an assembly 100 according to the disclosure. Cooling channels 19 which each run in a high-side cooling block 3, cooling channels 20 which run in the low-side cooling block 4, and coolant lines 9 which connect the cooling channels 19, 20 are illustrated. The arrows show the flow of the coolant in the cooling system.

FIG. 11 shows an exemplary cooling system, in which the cooling channels 19, 20 are connected to one another in series by the coolant lines 9 such that the flow of coolant is conducted through the cooling channels 19, 20 without branches. As shown, the cooling system is, for example, realized in the assembly 100 illustrated in FIGS. 1 to 10.

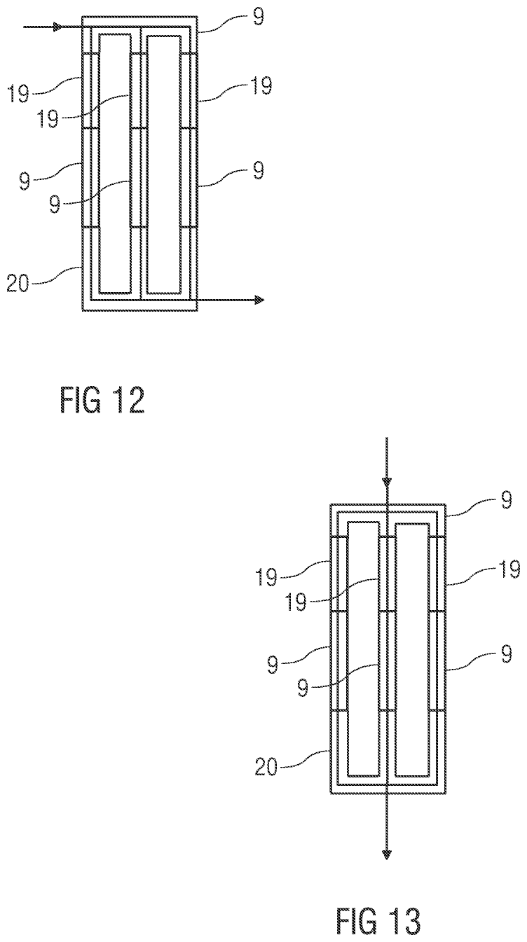

FIG. 12 shows an exemplary cooling system, in which the cooling channels 19, 20 are connected to one another partially in parallel by the coolant lines 9. Here, the flow of coolant is divided into the cooling channels 19 of the high-side cooling blocks 3 by two branches.

FIG. 13 shows an exemplary cooling system, in which the cooling channels 19, 20 are connected to one another in parallel by the coolant lines 9. Here, the flow of coolant is divided into the cooling channels 19 of the high-side cooling blocks 3 by one branch.

A number of implementations have been described. Nevertheless, it will be understood that various modifications may be made without departing from the spirit and scope of the disclosure. Accordingly, other implementations are within the scope of the following claims.

What is claimed is:

1. An electronic assembly comprising:
an electrical DC link having a positive pole and a negative pole;
at least one half bridge having an electronic high-side switch connected to the positive pole and an electronic low-side switch connected to the negative pole;
for each high-side switch a metal high-side cooling block on which the high-side switch is arranged;
at least one metal low-side cooling block on which at least one low-side switch is arranged; and
a closed metal housing in which the DC link, each half bridge and each cooling block are arranged and which has coolant connections for supplying and discharging a coolant, wherein:
the cooling blocks each have at least one cooling channel and the cooling channels are connected to one another and to the coolant connections such that a coolant is able to be conducted between the coolant connections through the cooling channels,
the high-side switch and the low-side switch of each half bridge are electrically connected by a connecting line, which has a half-bridge tap of the half bridge, and by a compensation line, which runs parallel to the connecting line, to the high-side switch and to the low-side switch and in which a half-bridge capacitor is arranged,
the high-side cooling blocks are electrically insulated from one another, from the positive pole and from each low-side cooling block, and
each low-side cooling block is insulated from the connecting lines and is electrically conductively connected to the negative pole and to the housing.

2. The electronic assembly claim 1, further comprising exactly one low-side cooling block on which all the low-side switches are arranged.

3. The electronic assembly of claim 1, wherein the DC link has a capacitor unit with a capacitance greater by a factor in a range from 10 to 50 than the capacitance of each half-bridge capacitor.

4. The electronic assembly of claim 1, wherein the connecting line and the compensation line of each half bridge run at a distance of at most 3 mm from one another.

5. The electronic assembly of claim 1, wherein each high-side cooling block is arranged at a distance of at most 10 mm from each low-side cooling block.

6. The electronic assembly of claim 1, wherein the connecting line and the compensation line of each half bridge have the same width or the same width and the same thickness.

7. The electronic assembly of claim 1, further comprising a multi-layer printed circuit board including:
a first layer having contact elements of the connecting lines, of the high-side switches and of the low-side switches of the half bridges, and
a second layer in which compensation line sections of the compensation lines run.

8. The electronic assembly of claim 7, wherein the printed circuit board comprises:
a third layer having an electrically conductive first voltage supply surface connected to the positive pole, and
a fourth layer having an electrically conductive second voltage supply surface connected to the negative pole.

9. The electronic assembly of claim 7, wherein the printed circuit board comprises a fifth layer on or in which all the half-bridge capacitors are arranged.

10. The electronic assembly of claim 1, wherein the housing is at least partially filled with a dielectric.

11. The electronic assembly of claim 10, wherein the dielectric has a relative permittivity of at least 3.

12. The electronic assembly of claim 10, wherein the dielectric is a thermoplastic or a thermoset or potting material.
